(19) United States
(12) Patent Application Publication
(10) Pub. No.: US 2012/0002755 A1
(43) Pub. Date: Jan. 5, 2012

(54) MULTI-LEVEL PULSE MODULATED POLAR TRANSMITTER AND METHOD OF GENERATING MULTI-LEVEL MODULATED ENVELOPE SIGNALS CARRYING MODULATED RF SIGNAL

(75) Inventors: Jau-Horng Chen, Taipei (TW); Yi-Jan Emery Chen, Taipei (TW)

(73) Assignee: NATIONAL TAIWAN UNIVERSITY, Taipei (TW)

(21) Appl. No.: 12/909,001

(22) Filed: Oct. 21, 2010

(30) Foreign Application Priority Data
Jul. 1, 2010 (TW) 099121632

(51) Int. Cl. H04L 27/12; H03K 7/10

(52) U.S. Cl. 375/302; 332/108

(57) ABSTRACT

A multi-level pulse modulated polar transmitter and a method of generating multi-level pulse modulated RF signals carrying phase information, in conjunction with a plurality of power amplifiers, so as to enhance the bandwidth of the transmitter and to reduce spurious emission and noise while synchronizing the phase and envelope of the input signals.

### BACKGROUND OF THE INVENTION

1. Field of the Invention

This invention relates to using a multi-level pulse modulation technique to implement a polar transmitter, and more particularly, to a multi-level pulse modulated polar transmitter and a method of generating multi-level envelope signals carrying modulated RF signal that may enhance the efficiency and bandwidth of a power amplifier and reduce out-of-band emissions.

2. Description of Related Art

In general, a power amplifier has long been known as the most power-consuming component in a radio-frequency (RF) transmitter. By improving the power amplifier efficiency, the overall battery life can be greatly increased. The envelope elimination and restoration (EER) method, which was first proposed in “Single-sideband transmission by envelope elimination and restoration” (Proc. of the IRE, pp. 803-806, July 1952, L. R. Kahn), may efficiently amplify an RF signal. The EER method splits the RF signal into a constant-envelope modulated signal and an envelope signal, amplifies the constant-envelope modulated signal, and restores the signal based on the envelope signal such that high overall power efficiency may be attained.

The EER method is implemented in “An envelope elimination and restoration power amplifier using a CMOS dynamic power supply circuit” (IEEE MTT-S Int. Microwave Symp. Dig., vol. 3, pp. 1591-1522, June 2004, J.-H. Chen, K. U-Yen, and J. S. Kenney) and “L-band transmitter using Kahn EER technique” (IEEE Trans. Microwave Theory Tech., vol. 46, no. 12, pp. 2220-2225, December 1998, F. H. Raab, B. E. Sigmon, R. G. Myers, and R. M. Jackson), in which a highly efficient power supply circuit is used to dynamically modulate the drain or collector of a non-linear, but highly efficient RF power amplifier. One of the major problems in implementing a Kahn EER transmitter is to synchronize the phase and envelope paths. The non-synchronization of the phase and envelope paths may create unwanted out-of-band emissions. Conventional EER transmitters use an L-C low-pass filter to filter the output of the switching envelope amplifier or dynamic bias circuit. The low-pass filter, however, creates significant delay that requires the phase data to be delayed accordingly using shift registers or delay circuits. For these transmitters, the phase path may require as many as 16 bits per clock for storage. Using the shift registers to store such data may adversely increase the area and cost of the transmitter.

Pulse modulation of the input signals using sigma-delta modulation (Σ-Δ Modulation) for implementing a Kahn EER transmitter has been proposed in “An improved Kahn transmitter architecture based on Delta-Sigma Modulation” (IEEE MTT-S Int. Microwave Symp. Dig., vol. 3, pp. 1327-1330, June 2004, Y. Wang), “An EER transmitter architecture with burst-width envelope modulation based on triangle-wave comparison PWM” (Proc. IEEE Int. Symp. PIMRC, pp. 1-5, September 2007, M. Taromaru, N. Ando, T. Kodera, and K. Yano) and “A transmitter architecture for nonconstant-envelope modulated modulation” (IEEE Trans. Circuit and Syst. II, vol. 53, no. 1, pp. 13-17, January 2006, C. Berland, I. Hibon, J. F. Bercher, M. Villegas, D. Belot, D. Pache, and V. Le Goasccoz). The main benefit of using this technique is the omission of the low-pass filter in the envelope path. By omitting the low-pass filter, the delay in the envelope path is reduced significantly, and hence synchronizing the phase and envelope paths using shift registers may be simplified. However, the use of the pulse-modulated EER method requires high-quality band-pass filters to filter the unwanted out-of-band emissions created by pulse modulation or SDM noises, which hampers the wide use of the EER method. Pulse modulation of the input signals using pulse-width modulation (PWM) was shown in “A transmitter architecture for nonconstant-envelope modulated modulation” (IEEE Trans. Circuit and Syst. II, vol. 53, no. 1, pp. 13-17, January 2006, C. Berland, I. Hibon, J. F. Bercher, M. Villegas, D. Belot, D. Pache, and V. Le Goasccoz), but was concluded as unattractive since spurious emissions are too high.

The aforesaid conventional EER transmitters require the use of envelope detectors and radio frequency (RF) limiters to obtain constant-envelope modulated RF signals. Thanks to the advancement of modern digital signal processing technology, it is now possible to directly generate the phase and envelope signals digitally to implement a polar transmitter. The polar transmitter may be applied in cellular phones for CDMA2000 and W-CDMA standards. In the related applications, a high-quality bass-pass filter is required at the output end of the transmitter, to suppress the unwanted out-of-band emissions generated from the PWM. The modern cellular phones supporting CDMA2000 and W-CDMA standards have high-quality surface-acoustic-wave (SAW) filters between the antennas and the power amplifiers. However, unless the PWM sampling frequency is sufficiently high, the SAW filter alone is not adequate to suppress the unwanted out-of-band emissions.

Therefore, how to provide a polar transmitter that may resolve the drawbacks of the prior art, to suppress the out-of-band emissions generated from the PWM and enhance the signal bandwidth and efficiency of the power amplifier, is crucial for handset power amplifier development.

### SUMMARY OF THE INVENTION

In view of the aforementioned problems of the prior art, the present invention provides a multi-level pulse modulated polar transmitter that includes an envelope signal input end for receiving input envelope signals; a constant-envelope modulated RF signal input end for receiving constant-envelope modulated RF input signals; a pulse modulation module for receiving the input envelope signals and generating a plurality of pulse modulation control signals of the input envelope signals; a plurality of signal modulation modules, each for receiving one of the constant-envelope modulated RF input signals and modulating the received one of the constant-envelope modulated RF input signals according to one of the multiple pulse modulation control signals, so as to generate pulsed-envelope modulated RF signals; and a plurality of power amplification modules, each for receiving the pulsed-envelope modulated RF signals carrying phase information, amplifying power of the pulsed-envelope modulated RF signals carrying phase information, and outputting the amplified pulsed-envelope modulated RF signals.

In another aspect of the present invention, a method of generating a multi-level pulsed-envelope modulated RF signal, comprising: receiving a plurality of corresponding pulse modulation control signals and constant-envelope modulated RF input signals by using a plurality of signal modulation modules; modulating the constant-envelope modulated RF input signals according to the pulse modulation control signals by using the signal modulation modules, so as to generate pulsed-envelope modulated RF signals carrying phase information; and combining the pulsed-envelope modulated RF signals generated by the signal modulation modules to generate multi-level pulse modulated RF signals.

In yet another aspect of the present invention, a method of generating multi-level pulse modulated RF signals, comprising: combining a plurality of pulsed-envelope modulated RF signals to generate multi-level pulse modulated RF signals.

Compared to the prior art, the multi-level pulse modulated polar transmitter of the present invention performs pulse modulation and signal combining processes with multiple pulse modulation control signals, to generate multi-level envelope signals. Therefore, the resolution is enhanced and the envelope path and the phase path can be easily synchronized.

### BRIEF DESCRIPTION OF DRAWINGS

The invention can be more fully understood by reading the following detailed description of the preferred embodiments, with reference made to the accompanying drawings, wherein:

FIG. 1 is a functional diagram of a multi-level pulse modulated polar transmitter of a first embodiment according to the present invention;

FIG. 2 is a functional diagram of a multi-level pulse modulated polar transmitter of a second embodiment according to the present invention;

FIG. 3 is a functional diagram of a multi-level pulse modulated polar transmitter of a third embodiment according to the present invention;

FIG. 4 is an example of multiple pulse modulation control signals generated by pulse modulation modules according to the present invention;

FIG. 5 is an output spectrum of signals obtained by applying the circuit structure shown in FIG. 3 with a single level and multi-level pulse modulated at a central frequency of 836.5 MHz; and

FIG. 6 is a schematic diagram of a basic structure that implements a method of generating pulsed-envelope modulated RF signal carrying phase information within.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### The First Embodiment

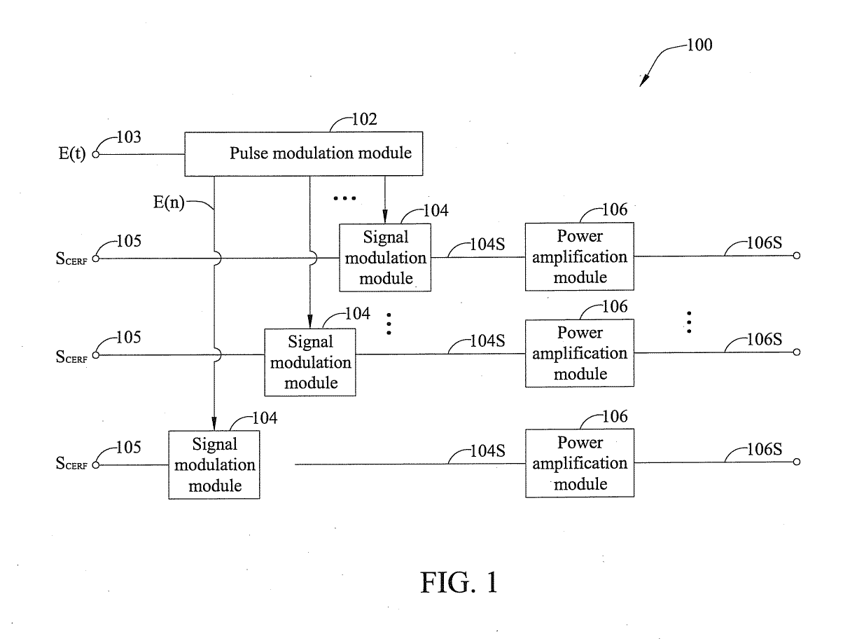

Refer to FIG. 1, which is a functional block diagram of a multi-level pulse modulated polar transmitter 100 of a first embodiment according to the present invention. The multi-level pulse modulated polar transmitter 100 comprises an envelope signal input end 103, a constant-envelope modulated RF signal input end 105, a pulse modulation module 102, a plurality of signal modulation modules 104, and a plurality of power amplification modules 106.

The envelope signal input end 103 receives envelope signals E(t). The constant-envelope modulated RF signal input end 105 receives constant-envelope modulated RF signals S_{CERF}.

The pulse modulation module 102 receives and pulse modulates the envelope signals E(t) to generate a plurality of pulse modulation control signals E(n) that may have the same or different pulse widths, pulses of each of the pulse modulation control signals E(n) having the same or different phases.

The signal modulation modules 104 receive the constant-envelope modulated RF signals S_{CERF}. Each of the signal modulation modules 104 modulates one of the constant-envelope modulated RF signals S_{CERF} that it receives according to one of the multiple pulse modulation control signals E(n), and generates a pulsed-envelope modulated RF signal 104S that carries phase information in a pulsed envelope. Accordingly, each of the signal modulation modules 104 may perform a pulse modulation process on one of the constant-envelope modulated RF signals S_{CERF} that it receives according to one of the multiple pulse modulation control signal E(n).

In the first embodiment, the signal modulation modules 104 may be implemented by various signal modulators, mixers, switches or logic circuits. Note that the multi-level pulse modulated polar transmitter 100 of the present invention may also employ other pulse modulation techniques similar to the pulse width modulation, such as the Σ-Δ modulation.

The power amplification modules 106 receive and amplify the pulsed-envelope modulated RF signals 104S output from the signal modulation modules 104, and output a plurality of output signals 106S with power being amplified.

Note that the envelope signals E(t) received at the envelope signal input end 103 are generated by RF input signals input at an RF input signal input end (not shown), and the constant-envelope modulated RF signals S_{CERF} received at the constant-envelope modulated RF signal input ends 105 are also generated by the RF input signals input at the input signal input end (not shown). The RF input signals generate the envelope signals E(t) and constant-envelope modulated RF signals S_{CERF}. The RF input signals may be in-phase quadrature signals (IQ modulated signals). Preferably, the envelope signals E(t) are the square root of a sum of squares of in-phase signals I(t) and quadrature signals Q(t) of the RF input signals, i.e., E(t)=\sqrt{I²(t)+Q²(t)}.

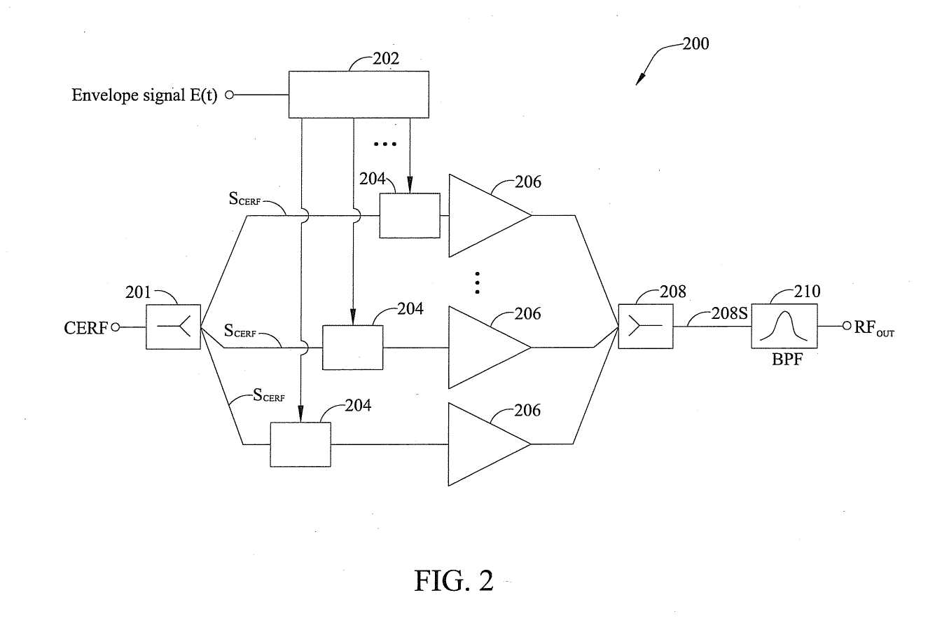

An embodiment of a polar transmitter of the present invention is described in accordance with FIG. 2.

### The Second Embodiment

Refer to FIG. 2, which is a circuit diagram of a multi-level pulse modulated polar transmitter 200 of the second embodiment according to the present invention. The multi-level pulse modulated polar transmitter 200 comprises a power splitter 201, a pulse modulator 202, a plurality of signal modulators 204, a plurality of RF power amplifiers 206, a power combiner 208 and a band-pass filter 210.

The power splitter 201 receives constant-envelope modulated RF signals CERF of RF input signals, and splits them into a plurality of constant-envelope modulated RF signals S_{CERF} that may have the same or different power. In the second embodiment, the total power of the constant-envelope modulated RF signals S_{CERF} is approximately equal to the power of the constant-envelope modulated RF signals CERF. Preferably, a Wilkinson power splitter may be used to implement the power splitter 201, for splitting the power of the constant-envelope modulated RF signals CERF of the RF input signals into a plurality of output paths.

The pulse modulator 202 receives and performs a pulse modulation process on envelope signals E(t) of RF input signals, and generates a plurality of pulse modulation signals that may have different pulse widths and phases. The multiple pulse modulation signals are then transmitted to the corresponding signal modulators 204. Pulses of each of the pulse modulated signals may have different phases and widths. In the second embodiment, the pulse modulator 202 may be a pulse-width modulator, Σ-Δ modulator, or a modulator generating a plurality of digital signals, as shown in FIG. 2.

The signal modulators 204 receive the corresponding constant-envelope modulated RF signals S_{CERF}. Each of the signal modulators 204 modulates one of the constant-envelope modulated RF signals S_{CERF} that it receives according to its corresponding pulse modulation signal, and generates pulsed-envelope modulated RF signals that carry phase information in a pulsed envelope. In the second embodiment, the Σ-Δ modulation technique, as well as the multiple pulse-width modulation technique, may be used to achieve the object of modulating the constant-envelope modulated RF signals S_{CERF}. In the present invention, the signal modulator 204 may be implemented by transistors such as a single-pole single-throw CMOS switch, discrete circuit switching components, or any other circuit components that may achieve a signal modulation effect. For example, the signal modulators 204 may be implemented by various signal modulators, mixers, switches or logic circuits. A plurality of weighted RF power amplifiers 206 that are in the same size may be implemented in the second embodiment.

The RF power amplifiers 206 receive and amplify the pulsed-envelope modulated RF signals output from the signal modulators 204, and output a plurality of output signals with power being amplified. In the second embodiment, class-D, -E, -F, or other high-efficiency power amplifiers can be used to implement the RF power amplifiers 206. Also, the RF power amplifiers 206 may have the same weights, to achieve a better output effect.

The power combiner 208 receives and combines the output signals output from the RF power amplifiers 206, and generates and outputs multi-level pulse modulated RF output signals 208S. In the second embodiment, a Wilkinson power combiner is used to implement the power combiner 208, for combining the output signals, with the power being amplified, into a single output path, and outputting the multi-level pulse modulated RF output signals 208S.

The band-pass filter 210 receives the multi-level pulse modulated RF output signals 208S output from the power combiner 208. The band-pass filter 210 has a predetermined passband, such that the RF output signals pass only signal components that have a frequency within the predetermined frequency band, i.e., RF_{OUT}.

In the second embodiment, a plurality of pulsed-envelope modulated RF signals may be combined to generate the multi-level pulse modulated RF output signals 208S.

### The Third Embodiment

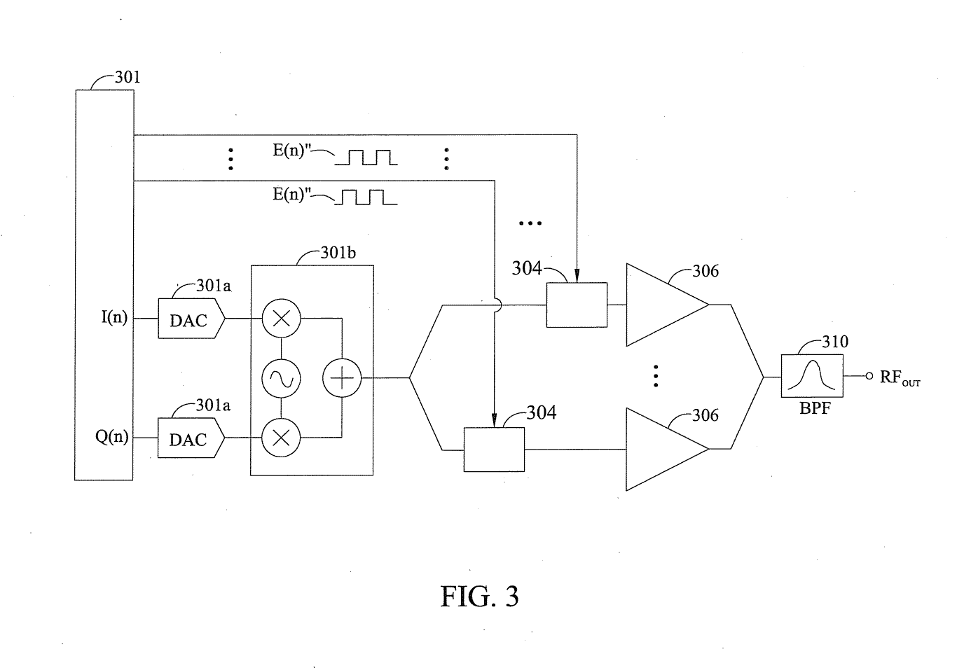

A multi-level pulse modulated polar transmitter according to the present invention may be applied to a wireless mobile device for various standards. Refer to FIG. 3, which describes in detail a multi-level pulse modulated polar transmitter of the third embodiment according to the present invention. In the third embodiment, a data generator 301 is used to generate multiple pulse modulation control signals E(n)″ and baseband IQ signals I(n) and Q(n) directly. A plurality of signal modulation modules 304 are the same as the signal modulators 204 described in the second embodiment shown in FIG. 2. The baseband IQ signals I(n) and Q(n) are orthogonal to each other, and are input to digital-analog converters 301a and vector modulator 301b sequentially to generate constant-envelope modulated RF signals.

Each of the signal modulation modules 304 modulates the received constant-envelope modulated RF signals according to one of the received pulse modulation control signals E(n)″ that receives, and generates corresponding pulsed-envelope modulated RF signals. The RF input signals applied to the circuit structure shown in FIG. 3 are set to be CDMA2000 1X signals at a carrier frequency of 836.5 MHz. A band-pass filter 310 is serially connected to the output ends of the RF power amplifiers 306 to filter unwanted switching harmonics.

The present invention uses multiple pulse modulation control signals to resolve the problems of spurious emissions. RF output signals are restored by filtering the multi-level pulse modulated RF signals.

The present invention uses a plurality of multiple pulse modulation control signals to perform a pulse modulation process in order to enhance the bandwidth of a transmitter and reduce spurious noises. This property has a significant effect on removing the out-of-band emissions created by the pulse modulation.

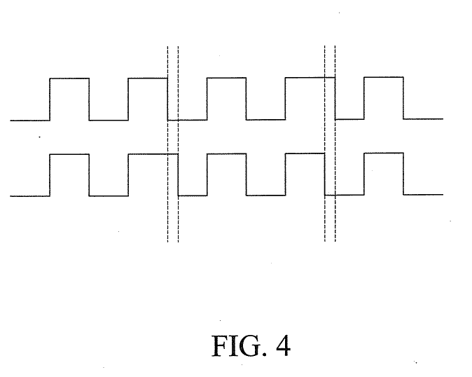

Refer to FIG. 4, which shows a plurality of pulse modulation control signals E(n), E(n)′ or multiple pulse modulation control signals E(n)″ generated by the pulse modulation module 102, pulse modulator 202 or data generator 301 in the aforesaid embodiments of the multi-level pulse modulated polar transmitter according to the present invention. Two pulse modulation control signals are used herein for an example. As shown in FIG. 4, some corresponding pulses of the two pulse modulation control signals may have the same pulse width and phase, and other corresponding pulses may have different pulse widths and phases. The multiple pulse modulation control signals in the aforesaid embodiment are provided herein to generate and combine pulse modulated RF signals carrying phase information in a pulsed envelope, by modulating the received constant-envelope modulated RF signals with the pulse modulation control signals, so as to generate the aforesaid multi-level pulse modulated RF output signals.

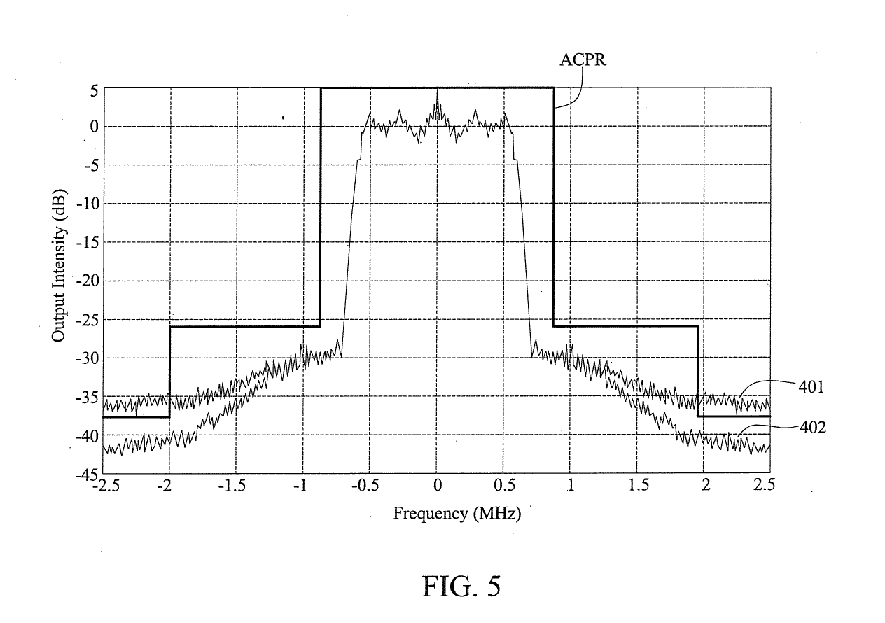

Refer to FIG. 5, which is an output spectrum of signals obtained by applying the circuit structure shown in FIG. 3 with a single level and two-way multi-level pulse modulation at a central frequency of 836.5 MHz. CDMA2000 1X signals with a center frequency of 836.5 MHz are used to demonstrate the polar transmitter of the present invention. Through the architecture shown in FIG. 3, the multi-level pulse modulated polar transmitter of the present invention is tested under a condition in which an output power is 24.5 dBm, and obtains a power-added efficiency (PAE) of 40.2%. A spectrum analyzer is used to measure an adjacent channel power ratio (ACPR1) and an alternate channel power ratio (ACPR2). The test result shows that ACPR1 and ACPR2 satisfy a standard defined by “TIA/EIA/98-E, Recommended Minimum Performance Standards for cdma2000 Spread Spectrum Mobile Stations.” Refer to FIG. 5, which is a representation result 402 of an output spectrum obtained by applying the circuit structure shown in FIG. 3 with a single level and a representation result 401 of an output spectrum by applying the circuit structure shown in FIG. 3 with multiple levels at a central frequency of 836.5 MHz. As comparing the ACPR2 measuring result, the ACPR2 may be improved by 4.5 dB through the use of the architecture of the present invention. The reduction of the spurious emission may be identified through the comparison of the output spectrums of PWM signals having different number of levels.

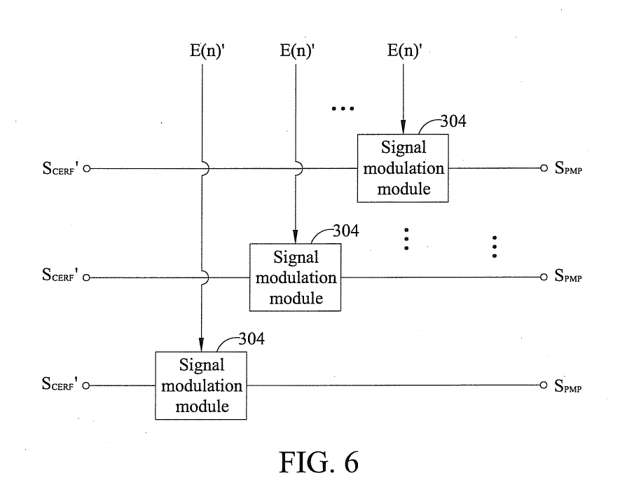

FIG. 6 is a schematic diagram of a basic structure that implements a method of generating multi-level pulsed-envelope modulated RF signal carrying phase information within. In the beginning, the method uses a plurality of signal modulation modules 304 to receive a plurality of pulse modulation control signals E(n)′ and a plurality of constant-envelope modulated RF input signals S_{CERF}′ carrying phase information. Each of the signal modulation modules 304 pulse modulates the received constant-envelope modulated RF input signals S_{CERF}′ that carry the phase information according to one of the received pulse modulation control signals E(n)′, and generates corresponding pulsed-envelope modulated RF signals S_{PMP} that carry phase information within. In the embodiment, the pulse modulation control signals E(n)′ may have different pulse widths and phases, and the constant-envelope modulated RF input signals S_{CERF}′ that carry phase information within.

Compared to the prior art, the multi-level pulse modulated polar transmitter of the present invention uses a plurality of pulse-envelope modulated RF signals to generate a multi-level pulse modulated RF signal carrying phase information within.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A multi-level pulse modulated polar transmitter, comprising:
an envelope signal input end for receiving input envelope signals;
a constant-envelope modulated RF signal input end for receiving constant-envelope modulated RF input signals;
a pulse modulation module for receiving the envelope signals and generating a plurality of pulse modulation control signals of the envelope signals;
a plurality of signal modulation modules, each for receiving one of the constant-envelope modulated RF input signals and modulating the received one of the constant-envelope modulated RF input signals according to one of multiple pulse-width modulation control signals, so as to generate modulated RF signals carrying phase information in a pulsed envelope; and
a plurality of power amplification modules, each for receiving the pulsed-envelope modulated RF signals carrying the phase information, amplifying power of the pulsed-envelope modulated RF signals carrying the phase information, and outputting the amplified pulsed-envelope modulated RF signals carrying the phase information.

2. The multi-level pulse modulated polar transmitter of claim 1, wherein the pulse width-pulse modulation control signals are pulse signals that have the same or different pulse widths and phases.

3. The multi-level pulse modulated polar transmitter of claim 1, wherein the pulse modulation module is a pulse width modulator, a Σ-Δ modulator, or a modulator generating a plurality of digital signals.

4. The multi-level pulse modulated polar transmitter of claim 1, further comprising a power splitter for splitting RF input signals into a plurality of RF input signals.

5. The multi-level pulse modulated polar transmitter of claim 1, further comprising a power combiner for receiving and combining the amplified pulsed-envelope modulated RF signals carrying the phase information from the power amplification modules and generating multi-level pulse modulated RF output signals.

6. The multi-level pulse modulated polar transmitter of claim 5, further comprising a band-pass filter for receiving the multi-level pulse modulated RF output signals from the power combiner, the band-pass filter having a predetermined frequency band to filter out switching harmonic components of the multi-level pulse modulated RF output signals.

7. A method of generating multi-level pulse modulated RF signals carrying phase information, comprising:
receiving a plurality of corresponding pulse modulation control signals and constant-envelope modulated RF input signals by using a plurality of signal modulation modules;
modulating the constant-envelope modulated RF input signals according to the plurality of pulse modulation control signals by using the signal modulation modules, so as to generate pulsed-envelope modulated RF signals carrying the phase information; and
combining the pulsed-envelope modulated RF signals carrying the phase information generated by the signal modulation modules to generate multi-level pulse modulated RF signals carrying the phase information.

8. The method of claim 7, wherein the pulse modulation control signals are pulses or digital signals that are generated according to amplitudes of the envelope signals and have the same or different pulse widths, and each pulse has the same or different phase.

9. The method of claim 7, wherein the constant-envelope modulated RF input signals have constant envelopes.

10. A method of generating multi-level pulse modulated RF signals, comprising:
combining a plurality of pulsed-envelope modulated RF signals to generate multi-level pulse modulated RF signals carrying phase information.
